(19) United States
(12) Patent Application Publication
(10) Pub. No.: US 2025/0355133 A1
(43) Pub. Date: Nov. 20, 2025

(54) APPARATUS AND METHOD OF PREDICTING PHOTOVOLTAIC POWER GENERATION AMOUNT

(71) Applicant: HANWHA SOLUTIONS CORPORATION, Seoul (KR)

(72) Inventors: Jung Woo SEO, Seoul (KR); Sang Won YUN, Seoul (KR)

(73) Assignee: HANWHA SOLUTIONS CORPORATION, Seoul (KR)

(21) Appl. No.: 19/196,412

(22) Filed: May 1, 2025

(30) Foreign Application Priority Data
May 16, 2024 (KR) 10-2024-0063955

(51) Int. Cl. G01W 1/10; G01R 21/133; G06N 3/045; G06N 3/09; G06V 10/774; G06V 10/82; G06V 20/50

(52) U.S. Cl. CPC G01W 1/10; G01R 21/133; G06N 3/045; G06N 3/09; G06V 10/774; G06V 10/82; G06V 20/50

(57) ABSTRACT

A method of predicting a photovoltaic power generation amount according to an embodiment may include predicting a sky image of a next time by analyzing sky images captured from a past time to a present time and meteorological data from the past time to the present time, predicting a solar radiation amount of the next time by analyzing the sky image of the next time, a clear-sky solar radiation amount of the next time, and meteorological data of the next time, which are generated as a result of the prediction, and predicting a photovoltaic power generation amount of the next time by analyzing the solar radiation amount of the next time and the meteorological data of the next time, which are generated as a result of the prediction, and power plant specification data.

### CROSS-REFERENCE TO RELATED APPLICATION

This application is based on and claims priority under 35 U.S.C. § 119 to Korean Patent Application No. 10-2024-0063955, filed on May 16, 2024, in the Korean Intellectual Property Office, the disclosure of which is incorporated by reference herein in its entirety.

### BACKGROUND

### 1. Field

The disclosure relates to a device and method of predicting photovoltaic power generation amount.

### 2. Description of the Related Art

As part of renewable energy, there is photovoltaic power generation. Photovoltaic power generation converts light from the sun into electrical energy using the photovoltaic effect. Because photovoltaic power generation is greatly affected by environmental factors such as weather and climate, predicting photovoltaic power generation amount is very important.

The background technology described above is technical information that the inventor possessed for deriving the disclosure or acquired in the process of deriving the disclosure, and cannot necessarily be considered as publicly known technology disclosed to the general public prior to the application for the disclosure.

### SUMMARY

An object of the disclosure is to predict a solar radiation amount by using sky images around a photovoltaic power generation plant and to accurately predict a photovoltaic power generation amount based on the solar radiation amount.

Objects to be solved by the disclosure are not limited to the problems mentioned above, and other objects and advantages of the disclosure that are not mentioned may be understood by the following description, and will be more clearly understood by embodiments of the disclosure. In addition, it will be appreciated that the objects and advantages to be solved by the disclosure may be realized by the means and combinations thereof indicated in the patent claims.

A device for predicting a photovoltaic power generation amount according to an embodiment is a device for predicting a photovoltaic power generation amount, and may include at least one processor and at least one memory operably connected to the at least one processor, wherein the at least one processor is configured to predict a sky image of a next time by analyzing sky images captured from a past time to a present time and meteorological data from the past time to the present time, predict a solar radiation amount of the next time by analyzing the sky image of the next time and a clear-sky solar radiation amount of the next time, and meteorological data of the next time, which are generated as a result of the prediction, and predict a photovoltaic power generation amount of the next time by analyzing the solar radiation amount of the next time and the meteorological data of the next time, which are generated as a result of the prediction, and power plant specification data.

A method of predicting a photovoltaic power generation amount according to an embodiment is a method of predicting a photovoltaic power generation amount performed by a processor of device for predicting a photovoltaic power generation amount, and may include predicting a sky image of a next time by analyzing sky images captured from a past time to a present time and meteorological data from the past time to the present time, predicting a solar radiation amount of the next time by analyzing the sky image of the next time, a clear-sky solar radiation amount of the next time, and meteorological data of the next time, which are generated as a result of the prediction, and predicting a photovoltaic power generation amount of the next time by analyzing the solar radiation amount of the next time and the meteorological data of the next time, which are generated as a result of the prediction, and power plant specification data.

In addition, other methods for implementing the disclosure, other systems, and computer-readable recording media storing a computer program for executing the method may be further provided.

Other aspects, features and advantages other than those described above will become apparent from the following drawings, claims and detailed description of the disclosure.

### BRIEF DESCRIPTION OF THE DRAWINGS

These and/or other aspects will become apparent and more readily appreciated from the following description of the embodiments, taken in conjunction with the accompanying drawings in which:

FIG. 1 is a block diagram schematically illustrating a configuration of a device for predicting photovoltaic power generation according to an embodiment;

FIG. 2 is a detailed diagram of the device for predicting photovoltaic power generation illustrated in FIG. 1;

FIG. 3 is a block diagram schematically illustrating a configuration of a device for predicting photovoltaic power generation according to another embodiment; and

FIG. 4 is a flowchart to describe a method of predicting photovoltaic power generation according to an embodiment.

### DETAILED DESCRIPTION

The advantages and features of the disclosure and the methods for achieving them will become apparent with reference to the embodiments described in detail together with the accompanying drawings. However, the disclosure is not limited to the embodiments presented below, but may be implemented in various different forms, and should be understood to include all transformations, equivalents, or substitutes included in the spirit and technical scope of the disclosure. The embodiments presented below are provided so that this disclosure will be complete and will fully convey the scope of the disclosure to those skilled in the art to which the disclosure pertains. In the description of the disclosure, if it is determined that a detailed description of a related known technology may obscure the gist of the disclosure, the detailed description is omitted.

The terminology used in this application is used only to describe particular embodiments and is not intended to limit the disclosure. Singular expressions include plural expressions unless the context clearly indicates otherwise. In the application, it should be understood that terms such as “include” or “have” are intended to specify the presence of a feature, number, step, operation, component, part or combination thereof described in the specification, but do not exclude in advance the possibility of the presence or addition of one or more other features, numbers, steps, operations, components, parts or combinations thereof. The terms first, second, etc. may be used to describe various components, but the components should not be limited by these terms. The above terms are used solely to distinguish one component from another.

In addition, in the disclosure, a “unit” may be a hardware component such as a processor or a circuit, and/or a software component executed by a hardware component such as a processor.

In the application, an artificial intelligence algorithm may be used to predict photovoltaic power generation. Here, artificial intelligence (AI) is a field of computer engineering and information technology that studies methods to enable computers to think, learn, and self-develop as human intelligence can, and may mean enabling computers to imitate human intelligent behavior. Also, AI does not exist in itself, but is directly or indirectly related to many other fields of computer science. In particular, in modern times, attempts have been made very actively to introduce AI elements into various fields of information technology and utilize the AI elements to solve problems in those fields. Machine learning is a branch of AI that may include areas of study that give computers the ability to learn without being explicitly programmed. In particular, machine learning is a technology that studies and builds systems and algorithms that learn based on empirical data, make predictions, and improve their own performance. Rather than executing strictly defined, static program instructions, machine learning algorithms may build specific models to make predictions or decisions based on input data. Both unsupervised learning and supervised learning may be used as machine learning methods for these artificial neural networks. In addition, deep learning technology, a type of machine learning, may learn at multiple levels at a deep level based on data. Deep learning may be defined as a set of machine learning algorithms that extract key data from multiple data sets as the level increases.

Hereinafter, embodiments according to the disclosure are described in detail with reference to the attached drawings. When describing with reference to the attached drawings, identical or corresponding components are assigned the same reference numerals, and redundant descriptions thereof are omitted.

In the following embodiments, the terms first, second, etc. are not used in a limiting sense but are used for the purpose of distinguishing one component from another.

In the following embodiments, singular expressions include plural expressions unless the context clearly indicates otherwise.

In the following embodiments, terms such as “include” or “have” mean that a feature or component described in the specification is present, and do not exclude in advance the possibility that one or more other features or components may be added.

In cases where an embodiment is otherwise feasible, specific process sequences may be performed in a different order than described. For example, two processes described sequentially may be performed substantially simultaneously, or may proceed in the reverse order from that described.

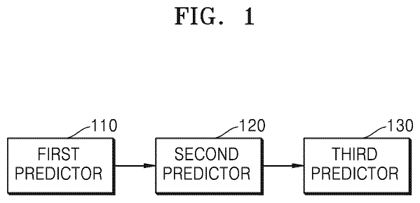

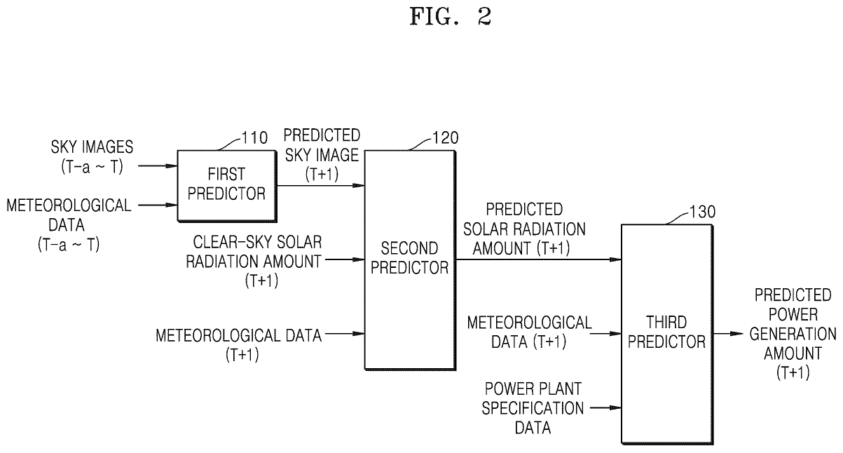

FIG. 1 is a block diagram schematically illustrating a configuration of a device for predicting photovoltaic power generation according to an embodiment, and FIG. 2 is a detailed diagram of the device for predicting photovoltaic power generation illustrated in FIG. 1. Referring to FIGS. 1 and 2, a device for predicting photovoltaic power generation amount 100 may include a first predictor 110, a second predictor 120, and a third predictor 130.

The first predictor 110 may predict a sky image of a next time T+1 by analyzing sky images captured from a past time T−a to a present time T and meteorological data from the past time T−a to the present time T.

In an embodiment, a sky image may include a sky image at a spot where a photovoltaic power generation plant is located. As an embodiment, a photovoltaic power generation plant (not shown) may be installed with a camera system (not shown) capable of capturing sky images at preset time intervals (e.g., every hour or every 30 minutes, etc.). The first predictor 110 may receive sky images captured at preset time intervals from the camera system. In another embodiment, a drone (not shown) may be used to capture sky images having high resolution at preset time intervals. The drone may capture precise sky images from a desired spot and height. The first predictor 110 may receive sky images captured from a drone at preset time intervals. In another embodiment, a worker working at a photovoltaic power generation plant may receive sky images captured at preset time intervals by using a smartphone or camera. The first predictor 110 may receive sky images captured at preset time intervals from the worker's smartphone or camera.

In an embodiment, the meteorological data may include an average value of each of the temperature, precipitation amount, wind speed, snowfall amount, solar radiation amount, and total cloud cover amount at a spot where a photovoltaic power generation plant is located. In an embodiment, the meteorological data may be collected from a weather station.

The first predictor 110 may predict a sky image of the next time T+1 corresponding to the sky images captured from the past time T−a to the present time T and the meteorological data from the past time T−a to the present time T by using a first deep neural network model that predicts the sky image of the next time T+1 based on the sky images captured from the past time T−a to the present time T and the meteorological data. In an embodiment, the first deep neural network model may include a model trained in a supervised learning manner with first training data that uses sky images captured from the past time T−a to the present time T and meteorological data from the past time T−a to the present time T as input and the sky image of the next time T+1 as a label.

The first predictor 110 may train the initially set first deep neural network model in a supervised learning manner by using the labeled first training data. Here, the initially set first deep neural network model is an initial model designed to be configured as a model capable of predicting the sky image of the next time T+1 based on the sky images captured from the past time T−a to the present time T and meteorological data from the past time T−a to the present time T, and parameter values may be set to arbitrary initial values. The initial model may be trained through the first training data described above, and the parameter values may be optimized so that a first prediction model may be completed to be capable of accurately predicting the sky image of the next time T+1 corresponding to the sky images captured from the past time T−a to the present time T and the meteorological data from the past time T−a to the present time T.

In an embodiment, past time may include a point in time (e.g., a) before the present time T. For example, in case that a is 24 hours, then the past time T−a may mean a point in time of one day ago. For example, in an embodiment, the next time T+1 may represent a point in time immediately following the present time T.

The second predictor 120 may predict a solar radiation amount of the next time T+1 by analyzing the sky image of the next time T+1, a clear-sky solar radiation amount of the next time T+1, and the meteorological data of the next time T+1, which are generated as a result of the prediction by the first predictor 110.

In an embodiment, a clear sky may refer to a sky with few or no clouds. In an embodiment, the second predictor 120 may use a fourth deep neural network model to predict the clear-sky solar radiation amount of the next time T+1. Here, the fourth deep neural network model may use a specialized algorithm to distinguish it from first to third deep neural network models disclosed in the claims to be described below.

The second predictor 120 may predict the solar radiation amount of the next time T+1 corresponding to the sky image of the present time T and the meteorological data of the present time T by using the fourth deep neural network model that predicts the solar radiation amount of the next time T+1 based of the sky image of the present time T and the meteorological data of the present time T. Here, the fourth deep neural network model may include a model trained in a supervised learning manner with fourth training data that uses the sky image of the present time T and the meteorological data of the present time T as input and the solar radiation amount of the next time T+1 as a label.

In an embodiment, the second predictor 120 may use a fifth deep neural network model to predict meteorological data of the next time T+1. Here, the fifth deep neural network model may use a specialized algorithm to distinguish it from the first to fourth deep neural network models.

The second predictor 120 may predict the meteorological data of the next time T+1 corresponding to the meteorological data from the past time T−a to the present time T, date and time data, and geographical location data by using the fifth deep neural network model that predicts the meteorological data of the next time T+1 based on the meteorological data from the past time T−a to the present time T, the date and time data, and the geographical location data. Here, the fifth deep neural network model may include a model trained in a supervised learning manner by fifth training data that uses the meteorological data from the past time T−a to the present time T, the date and time data, and the geographical location data as input and the meteorological data of the next time T+1 as a label.

The second predictor 120 may predict the solar radiation amount of the next time T+1 corresponding to the sky image of the next time T+1 generated as the result of the prediction by the first predictor 110, the clear-sky solar radiation amount of the next time T+1, and the meteorological data of the next time T+1 by using a second deep neural network model that predicts the solar radiation amount of the next time T+1 based on the sky image of the next time T+1, the clear-sky solar radiation amount of the next time T+1, and the meteorological data of the next time T+1. In an embodiment, the second deep neural network model may include a model trained in a supervised learning manner with second training data that uses the sky image of the next time, the clear-sky solar radiation amount of the next time, and meteorological data of the next time as input and the solar radiation amount of the next time as a label.

The second predictor 120 may train the initially set second deep neural network model in a supervised learning manner by using labeled second training data. Here, the initially set second deep neural network model is an initial model designed to be configured as a model capable of predicting the solar radiation amount of the next time T+1 based on the sky image of the next time T+1, the clear-sky solar radiation amount of the next time T+1, and the meteorological data of the next time T+1, and parameter values may be set to arbitrary initial values. The initial model may be trained through the second training data described above, and the parameter values may be optimized so that a second prediction model may be completed to be capable of accurately predicting the solar radiation amount of the next time T+1 corresponding to the sky image of the next time T+1, the clear-sky solar radiation amount of the next time T+1, and the meteorological data of the next time T+1.

The third predictor 130 may predict the photovoltaic power generation amount of the next time T+1 by analyzing the solar radiation amount of the next time T+1 and the meteorological data of the next time T+1, which are generated as a result of the prediction by the second predictor 120, and power plant specification data.

In an embodiment, the power plant specification data may reflect the operating characteristics and facility status of the photovoltaic power generation plant. The power plant specification data may include the maximum amount of electricity that a photovoltaic panel may produce, the type of the photovoltaic panel used (e.g., monocrystalline, polycrystalline, bifacial, etc.) and the energy conversion efficiency of the corresponding panel, the installed direction (e.g., south-facing, north-facing, etc.) and slope of the panels, the geographical location of the power plant, the time the power plant began operating and the operating period until the present, and the regular maintenance and repair records of the power plant, or the like.

The third predictor 130 may predict the photovoltaic power generation amount of the next time T+1 corresponding to the solar radiation amount of the next time T+1 and the meteorological data of the next time T+1, which are generated as the result of the prediction by the second predictor 120, and the power plant specification data by using a third deep neural network model that predicts the photovoltaic power generation amount of the next time T+1 based on the solar radiation amount of the next time T+1, the meteorological data of the next time T+1, and the power plant specification data. In an embodiment, the third deep neural network model may include a model trained in a supervised learning manner with third training data that uses the solar radiation amount of the next time T+1, the meteorological data of the next time T+1, and the power plant specification data labels and the photovoltaic power generation amount of the next time T+1 as a label.

The third predictor 130 may train the initially set third deep neural network model in a supervised learning manner by using labeled third training data. Here, the initially set third deep neural network model is an initial model designed to be configured as a model capable of predicting the photovoltaic power generation amount of the next time T+1 based on the solar radiation amount of the next time T+1, the meteorological data of the next time T+1, and the power plant specification data, and parameter values may be set to arbitrary initial values. The initial model may be trained through the third training data described above, and the parameter values may be optimized so that a third prediction model may be completed to be capable of accurately predicting the photovoltaic power generation amount of the next time T+1 corresponding to the solar radiation amount of the next time T+1, the meteorological data of the next time T+1, and the power plant specification data.

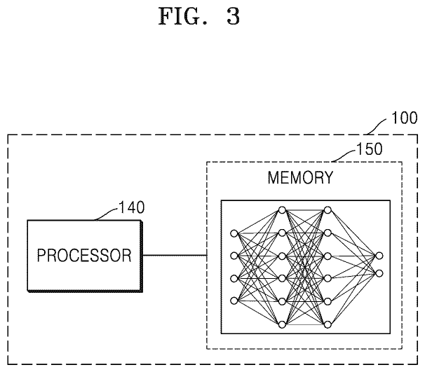

FIG. 3 is a block diagram schematically illustrating a configuration of a device for predicting photovoltaic power generation according to another embodiment. In the following description, any parts that overlap the descriptions of FIGS. 1 and 2 are omitted. Referring to FIG. 3, the device for predicting photovoltaic power generation amount 100 according to another embodiment may include a processor 140 and a memory 150.

In an embodiment, the processor 140 may process the functions performed by the first predictor 110, the second predictor 120, and the third predictor 130 disclosed in FIGS. 1 and 2.

The processor 140 may control the overall operation of the device for predicting photovoltaic power generation amount 100. Here, the ‘processor’ may mean, for example, a data processing device built into hardware, having a physically structured circuit to perform a function expressed by a code or instruction included in a program. Examples of such a data processing device built into hardware may include processing devices, such as a microprocessor, a central processing unit, a processor core, a multiprocessor, an application-specific integrated circuit (ASIC), and a field programmable gate array (FPGA), but the scope of the disclosure is not limited thereto.

The memory 150 may be operably connected to the processor 140 and store at least one code associated with an operation performed by the processor 140.

In some embodiments, the memory 150 may perform a function of temporarily or permanently storing data processed by the processor 140. Here, the memory 150 may include a magnetic storage medium or a flash storage medium, but the scope of the disclosure is not limited thereto. The memory 150 may include internal memory and/or external memory, and may include volatile memory such as dynamic random-access memory (DRAM), static random access memory (SRAM), or synchronous dynamic random-access memory (SDRAM), nonvolatile memory such as one-time programmable read-only memory (OTPROM), programmable read-only memory (PROM), erasable programmable read-only memory (EPROM), electrically erasable programmable read-only memory (EEPROM), mask read-only memory (ROM), flash ROM, NAND flash memory, or NOR flash memory, flash drives such as solid-state drive (SSD), CompactFlash (CF) card, Secure Digital (SD) card, Micro-SD card, Mini-SD card, extreme Digital (xD) card, or memory stick, or storage devices such as hard disk drive (HDD).

In an embodiment, the device for predicting photovoltaic power generation amount 100 may exist independently in the form of a server, or a function of predicting photovoltaic power generation amount provided by the device for predicting photovoltaic power generation amount 100 may be implemented in in the form of an application and loaded onto a user terminal (not shown). The user terminal may access the photovoltaic power generation amount prediction application and/or photovoltaic power generation amount prediction site provided by the device for predicting photovoltaic power generation amount 100 to receive a photovoltaic power generation amount prediction service. In an embodiment, the device for predicting photovoltaic power generation amount 100 may further include a communication module (not shown) configured to perform communication with the user terminal and an external device (e.g., a camera system, a drone, a weather station, etc.).

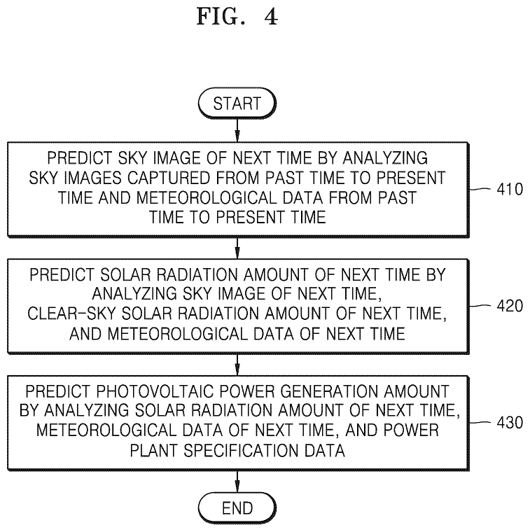

FIG. 4 is a flowchart to describe a method of predicting photovoltaic power generation according to an embodiment. In the following description, any parts that overlap the descriptions of FIGS. 1 to 3 are omitted. A method of predicting photovoltaic power generation amount according to an embodiment is described assuming that the device for predicting photovoltaic power generation amount 100 is performed by the processor 140 with the help of peripheral components.

Referring to FIG. 4, in operation S410, the processor 140 may predict a sky image of a next time T+1 by analyzing sky images captured from a past time T−a to a present time T and meteorological data from the past time T−a to the present time T. In an embodiment, when predicting the sky image of the next time T+1, the processor 140 may predict the sky image of the next time T+1 corresponding to the sky images captured from the past time T−a to the present time T and meteorological data from the past time T−a to the present time T by using a first deep neural network model that predicts the sky image of the next time T+1 based on the sky images captured from the past time T−a to the present time T and the meteorological data from the past time T−a to the present time T. In an embodiment, the first deep neural network model may include a model trained in a supervised learning manner with first training data that uses sky images captured from the past time T−a to the present time T and the meteorological data from the past time T−a to the present time T as an input and the sky image of the next time T+1 as a label.

In operation S420, the processor 140 may predict a solar radiation amount of the next time T+1 by analyzing the sky image of the next time T+1, a clear-sky solar radiation amount of the next time T+1, and the meteorological data of the next time T+1, which are generated as a result of the prediction. When predicting the solar radiation amount of the next time T+1, the processor 140 may predict the solar radiation amount of the next time T+1 corresponding to the sky image of the next time T+1 generated as the result of the prediction, the clear-sky solar radiation amount of the next time T+1, and the meteorological data of the next time T+1 by using a second deep neural network model that predicts the solar radiation amount of the next time T+1 based on the sky image of the next time T+1, the clear-sky solar radiation amount of the next time T+1, and the meteorological data of the next time T+1. In an embodiment, the second deep neural network model may include a model trained in a supervised learning manner with second training data that uses the sky image of the next time T+1, the clear-sky solar radiation amount of the next time T+1, and the meteorological data of the next time T+1 as input and the solar radiation amount of the next time T+1 as a label.

In operation S430, the processor 140 may predict the photovoltaic power generation amount of the next time T+1 by analyzing the solar radiation amount of the next time T+1 and the meteorological data of the next time T+1, which are generated as a result of the prediction, and power plant specification data. In an embodiment, when predicting the photovoltaic power generation amount of the next time T+1, the processor 140 may predict the photovoltaic power generation amount of the next time T+1 corresponding to the solar radiation amount of the next time T+1 and the meteorological data of the next time T+1, which are generated as a result of the prediction, and the power plant specification data by using a third deep neural network model that predicts the photovoltaic power generation amount of the next time T+1 based on the solar radiation amount of the next time T+1, the meteorological data of the next time T+1, and the power plant specification data. In an embodiment, the third deep neural network model may include a model trained in a supervised learning manner with third training data that uses the solar radiation amount of the next time T+1, the meteorological data of the next time T+1, and the power plant specification data as input and the photovoltaic power generation amount of the next time T+1 as a label.

According to an embodiment, the accuracy of predicting power generation amount may be improved by predicting a solar radiation amount using sky images around a photovoltaic power generation plant and predicting a photovoltaic power generation amount based on the solar radiation amount.

In some embodiments, measuring a photovoltaic power generation amount by using sky images around a power generation plant may contribute to improving the power generation planning and operational efficiency.

The embodiments of the disclosure described above may be implemented in the form of a computer program that may be executed through various components on a computer, and such a computer program may be recorded on a computer-readable medium. At this time, the medium may include a magnetic medium such as a hard disk, a floppy disk, and a magnetic tape, an optical recording medium such as CD-ROM and DVD, a magneto-optical medium such as a floptical disk, and a hardware device specifically configured to store and execute program instructions, such as ROM, RAM, and flash memory.

The computer program may be specially designed and configured for the disclosure or may be known and available to those skilled in the art in the computer software field. Examples of computer programs may include not only machine language code, such as that produced by a compiler, but also high-level language code that may be executed by a computer by using an interpreter or the like.

The use of the term “above” and similar referential terms in the specification of the disclosure (especially in the claims) may refer to both the singular and the plural. In addition, when a range is described in the disclosure, it is considered to include a disclosure that applies individual values belonging to the range (unless otherwise stated), and is the same as describing each individual value constituting the range in the detailed description of the disclosure.

Unless there is an explicit description or contradiction of the order of the operations constituting the method according to the disclosure, the operations may be performed in any suitable order. The disclosure is not necessarily limited to the order in which the above operations are described. The use of any examples or terms (e.g., “for example,” “etc.”) in the disclosure is merely intended to illustrate the disclosure in more detail and is not intended to limit the scope of the disclosure by reason of such examples or terms, unless otherwise limited by the claims. Furthermore, those skilled in the art will appreciate that various modifications, combinations and variations may be made according to design conditions and factors within the scope of the appended claims or their equivalents.

Therefore, the idea of the disclosure should not be limited to the embodiments described above, and not only the scope of the patent claims described below but also all scopes equivalent to or equivalently modified from the scope of the patent claims are included in the scope of the idea of the disclosure.

What is claimed is:

1. A method of predicting a photovoltaic power generation amount, performed by a processor of a device for predicting a photovoltaic power generation amount, the method comprising:
predicting a sky image of a next time by analyzing sky images captured from a past time to a present time and meteorological data from the past time to the present time;
predicting a solar radiation amount of the next time by analyzing the sky image of the next time, a clear-sky solar radiation amount of the next time, and meteorological data of the next time, which are generated as a result of the prediction; and
predicting a photovoltaic power generation amount of the next time by analyzing the solar radiation amount of the next time and the meteorological data of the next time, which are generated as a result of the prediction, and power plant specification data.

2. The method of claim 1, wherein
the predicting of the sky image of the next time comprises
predicting the sky image of the next time corresponding to the sky images captured from the past time to the present time and the meteorological data from the past time to the present time by using a first deep neural network model that predicts the sky image of the next time based on the sky images captured from the past time to the present time and the meteorological data from the past time to the present time, and
the first deep neural network model comprises
a model trained in a supervised learning manner with first training data that uses the sky images captured from the past time to the present time and the meteorological data from the past time to the present time as input and the sky image of the next time as a label.

3. The method of claim 1, wherein
the predicting of the solar radiation amount of the next time comprises
predicting the solar radiation amount of the next time corresponding to the sky image of the next time, a clear-sky solar radiation amount of the next time, and the meteorological data of the next time, which are generated as a result of the prediction, by using a second deep neural network model that predicts the solar radiation amount of the next time based on the sky image of the next time, the clear-sky solar radiation amount of the next time, and the meteorological data of the next time, and
the second deep neural network model comprises
a model trained in a supervised learning manner with second training data that uses the sky image of the next time, the clear-sky solar radiation amount of the next time, and the meteorological data of the next time as input and the solar radiation amount of the next time as a label.

4. The method of claim 1, wherein
the predicting of the photovoltaic power generation amount of the next time comprises
predicting the photovoltaic power generation amount of the next time corresponding to the solar radiation amount of the next time and the meteorological data of the next time, which are generated as a result of the prediction, and the power plant specification data, by using a third deep neural network model that predicts the photovoltaic power generation amount of the next time based on the solar radiation amount of the next time, the meteorological data of the next time, and the power plant specification data, and
the third deep neural network model comprises
a model trained in a supervised learning manner with third training data that uses the solar radiation amount of the next time, the meteorological data of the next time, and the power plant specification data as input and the photovoltaic power generation amount of the next time as a label.

5. A computer-readable recording medium having recorded thereon a computer program to cause a computer to execute the method of claim 1.

6. A device for predicting a photovoltaic power generation amount, comprising:
at least one processor; and
at least one memory operably connected to the at least one processor,
wherein the at least one processor is configured to:
predict a sky image of a next time by analyzing sky images captured from a past time to a present time and meteorological data from the past time to the present time;
predict a solar radiation amount of the next time by analyzing the sky image of the next time, a clear-sky solar radiation amount of the next time, and meteorological data of the next time, which are generated as a result of the prediction; and
predict a photovoltaic power generation amount of the next time by analyzing the solar radiation amount of the next time and the meteorological data of the next time, which are generated as a result of the prediction, and power plant specification data.

7. The device of claim 6, wherein
the at least one processor is configured to,
when predicting the sky image of the next time, predict the sky image of the next time corresponding to the sky images captured from the past time to the present time and the meteorological data from the past time to the present time by using a first deep neural network model that predicts the sky image of the next time based on the sky images captured from the past time to the present time and the meteorological data from the past time to the present time, and
the first deep neural network model comprises
a model trained in a supervised learning manner with first training data that uses the sky images captured from the past time to the present time and the meteorological data from the past time to the present time as input and the sky image of the next time as a label.

8. The device of claim 6, wherein
the at least one processor is configured to,
when predicting the solar radiation amount of the next time, predict the solar radiation amount of the next time corresponding to the sky image of the next time, a clear-sky solar radiation amount of the next time, and the meteorological data of the next time, which are generated as a result of the prediction, by using a second deep neural network model that predicts the solar radiation amount of the next time based on the sky image of the next time, the clear-sky solar radiation amount of the next time, and the meteorological data of the next time, and
the second deep neural network model comprises
a model trained in a supervised learning manner with second training data that uses the sky image of the next time, the clear-sky solar radiation amount of the next time, and the meteorological data of the next time as input and the solar radiation amount of the next time as a label.

9. The device of claim 6, wherein
the at least one processor is configured to,
when predicting the photovoltaic power generation amount of the next time, predict the photovoltaic power generation amount of the next time corresponding to the solar radiation amount of the next time and the meteorological data of the next time, which are generated as a result of the prediction, and the power plant specification data, by using a third deep neural network model that predicts the photovoltaic power generation amount of the next time based on the solar radiation amount of the next time, the meteorological data of the next time, and the power plant specification data, and
the third deep neural network model comprises
a model trained in a supervised learning manner with third training data that uses the solar radiation amount of the next time, the meteorological data of the next time, and the power plant specification data as input and the photovoltaic power generation amount of the next time as a label.
